(19) United States
(12) Patent Application Publication
(10) Pub. No.: US 2010/0127258 A1
(43) Pub. Date: May 27, 2010

(54) LCD PANEL HAVING SHARED SHORTING BARS FOR ARRAY INSPECTION AND PANEL INSPECTION

(76) Inventors: Liang-Hao Kang, Taipei County (TW); Yi-Cheng Tsai, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 12/538,154

(22) Filed: Aug. 9, 2009

(30) Foreign Application Priority Data
Nov. 26, 2008 (TW) 097145647

(51) Int. Cl. H01L 23/58; H01L 23/544

(52) U.S. Cl. 257/48; 257/E23.179; 257/E23.01

(57) ABSTRACT

An LCD panel includes a panel area, a plurality of shorting bars, a plurality of panel test pads, and a plurality of array test pads. The panel area includes a plurality of scan lines and a plurality of data lines. The plurality of shorting bars is located inside the panel area. The plurality of scan lines and the plurality of data lines are electrically connected to corresponding shorting bars of the plurality of shorting bars through a switch circuit. The plurality of panel test pads is located inside the panel area. The plurality of panel test pads is electrically connected to the plurality of shorting bars respectively. The plurality of array test pads is located outside the panel area. The plurality of array test pads is electrically connected to corresponding panel test pads of the plurality of panel test pads.

### BACKGROUND OF THE INVENTION

1. Field of the Invention

The present invention relates to a Liquid Crystal Display (LCD) panel using shorting bars for inspection, and more particularly, to an LCD panel having shared shorting bars for an array inspection and a panel inspection.

2. Description of the Prior Art

Please refer to FIG. 1. FIG. 1 is a diagram illustrating array test pads of a conventional LCD panel 100. The fabrication of the LCD panel 100 comprises an array process, a panel process, and a module process. After each process, a test is performed for excluding the defective LCD panels. An array inspection comprises a full contact test and a shorting bar test. The test pads 130 for the shorting bar test are disposed outside a panel area 110 of the LCD panel 100. In the full contact test, each of the scan lines are electrically connected to their corresponding test pads 120 respectively, and each of the data lines are electrically connected to their corresponding test pads 120 respectively as well, and then the probe contacts each test pad 120 for transmitting the required testing signals onto the test pads 120. Therefore, the test machine for the full contact test is not only easily broken-down because a large amount of probes is required, but also is incapable of testing the LCD panels of different size.

In the shorting bar test, as shown in FIG. 1, the scan lines are divided into odd scan lines and even scan lines. The odd scan lines are all electrically connected to the same shorting bar which is electrically connected to the test pad GO. The even scan lines are all electrically connected to the same shorting bar which is electrically connected to the test pad GE. In the same way, the data lines are divided into odd data lines and even data lines. The odd data lines are all electrically connected to the same shorting bar which is electrically connected to the test pad DO. The even data lines are all electrically connected to the same shorting bar which is electrically connected to the test pad DE. When using the shorting bars for the array inspection, only the test pads GO, GE, DO and DE are required to be contacted by the probe. Hence, in the shorting bar test, the amount of the probes can be reduced, and the testing machine can be utilized for testing the LCD panels of different size. However, since the test result of the full contact test is better (more detailed) than that of the shorting bar test, using a switch circuit for switching between the full contact test and the array inspection is more flexible for the user. The switch circuit comprises a first set of switches 151 and a second set of switches 152. The control ends of the first set of switches 151 are electrically connected to the test pad DSW. The control ends of the second set of the switches are electrically connected to the test pad GSW. When the switch circuit is turned on, the shorting bar test is executed for the array inspection. When the switch circuit is turned off, the full contact test is executed for the array inspection.

Please refer to FIG. 2. FIG. 2 is a diagram illustrating panel test pads of a conventional LCD panel. The panel test pads 160 are disposed inside the panel area 110 of the LCD panel. The short bar test is performed for the panel test. In the panel test, besides the data lines are divided into odd data lines and even data lines, the data lines are further divided into red (R) data lines, green (G) data lines, and blue (B) data lines. The first shorting bar 161 is electrically connected to the odd red pixel data lines. The second shorting bar 162 is electrically connected to the odd green pixel data lines. The third shorting bar 163 is electrically connected to the odd blue pixel data lines. The fourth shorting bar 164 is electrically connected to the even red pixel data lines. The fifth shorting bar 165 is electrically connected to the even green pixel data lines. The sixth shorting bar 166 is electrically connected to the odd blue pixel data lines. The seventh shorting bar 167 is electrically connected to the odd scan lines. The eighth shorting bar is electrically connected to the even scan lines. The shorting bars 161˜166 are electrically connected to the data lines through a switch circuit 171. The control ends of the switch circuits 171 are electrically connected to the test pad DSW. The shorting bars 167 and 168 are electrically connected to the scan lines through a switch circuit 172. The control ends of the switch circuits 172 are electrically connected to the test pad GSW. The switch circuits 171 and 172 are turned on only during the panel inspection of the LCD panel.

### SUMMARY OF THE INVENTION

The present invention provides an LCD panel having shared shorting bars for array inspection and panel inspection. The LCD panel comprises a panel area, a plurality of shorting bars, a plurality of panel test pads, and a plurality of array test pads. The panel area comprises a plurality of scan lines and a plurality of data lines. The plurality of shorting bars is disposed inside the panel area. The plurality of scan lines and the plurality of data lines are electrically connected to corresponding shorting bars of the plurality of shorting bars through a switch circuit. The plurality of panel test pads is disposed inside the panel area. The plurality of panel test pads is electrically connected to the plurality of shorting bars respectively. The plurality of array test pads is disposed outside the panel area. The plurality of array test pads is electrically connected to corresponding panel test pads of the plurality of panel test pads.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating array test pads of a conventional LCD panel.

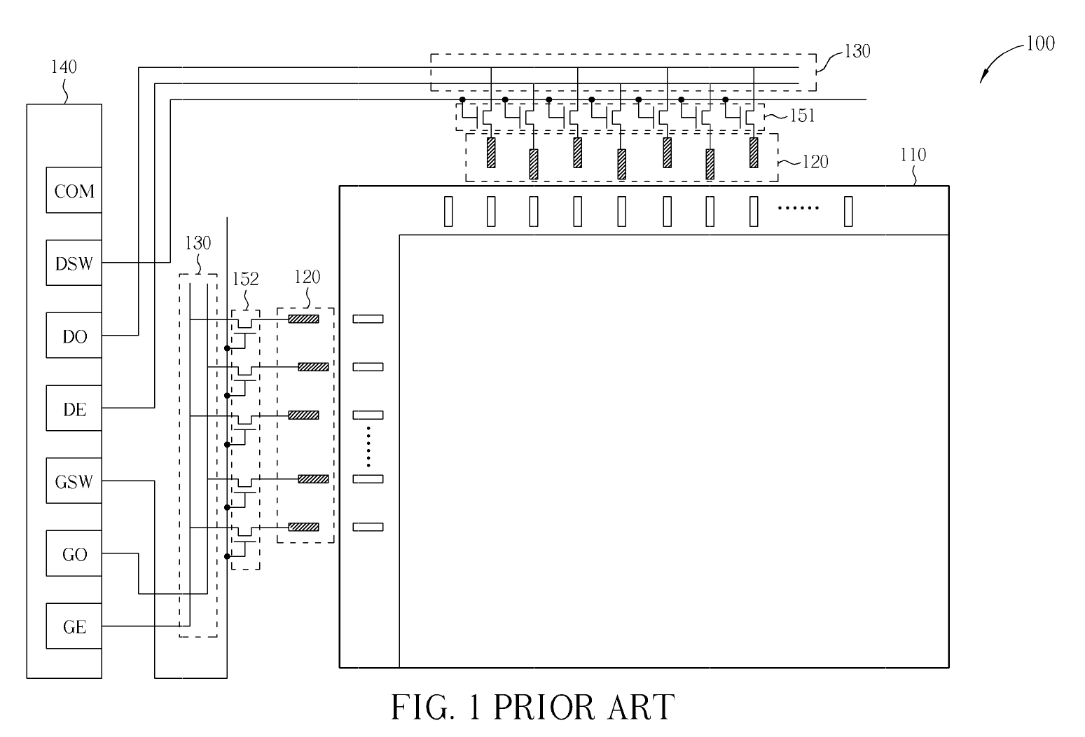

FIG. 2 is a diagram illustrating panel test pads of a conventional LCD panel.

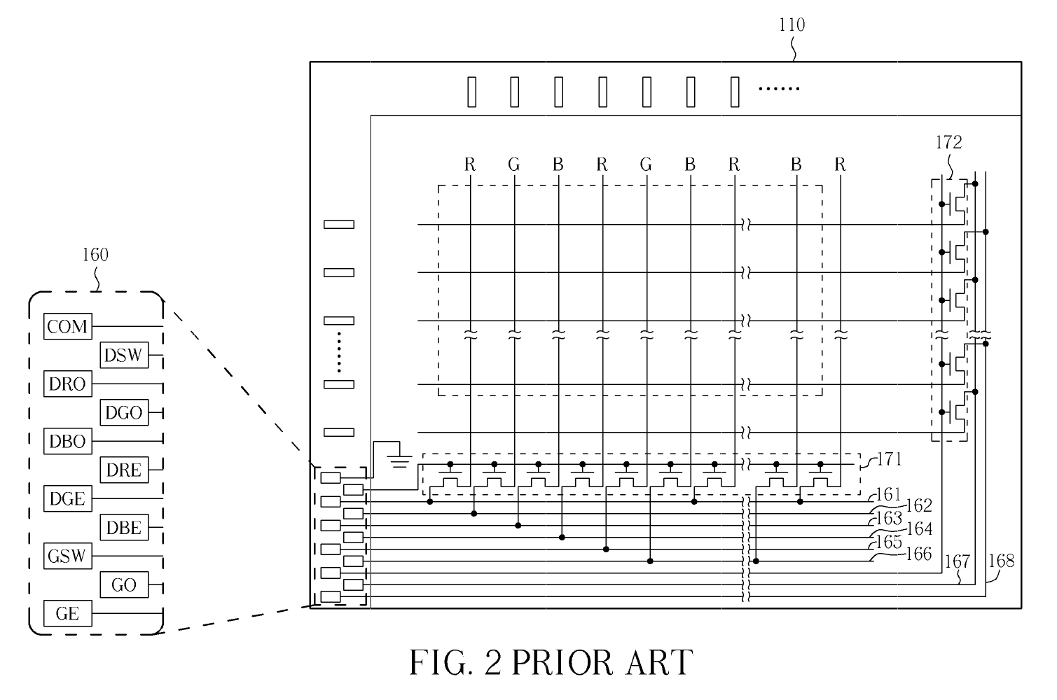

FIG. 3 is a diagram illustrating an LCD panel of the present invention having shared shorting bars for the array inspection and the panel inspection.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ” Also, the term “electrically connect” is intended to mean either an indirect or direct electrical connection. Accordingly, if one device is coupled to another device, that connection may be through a direct electrical connection, or through an indirect electrical connection via other devices and connections.

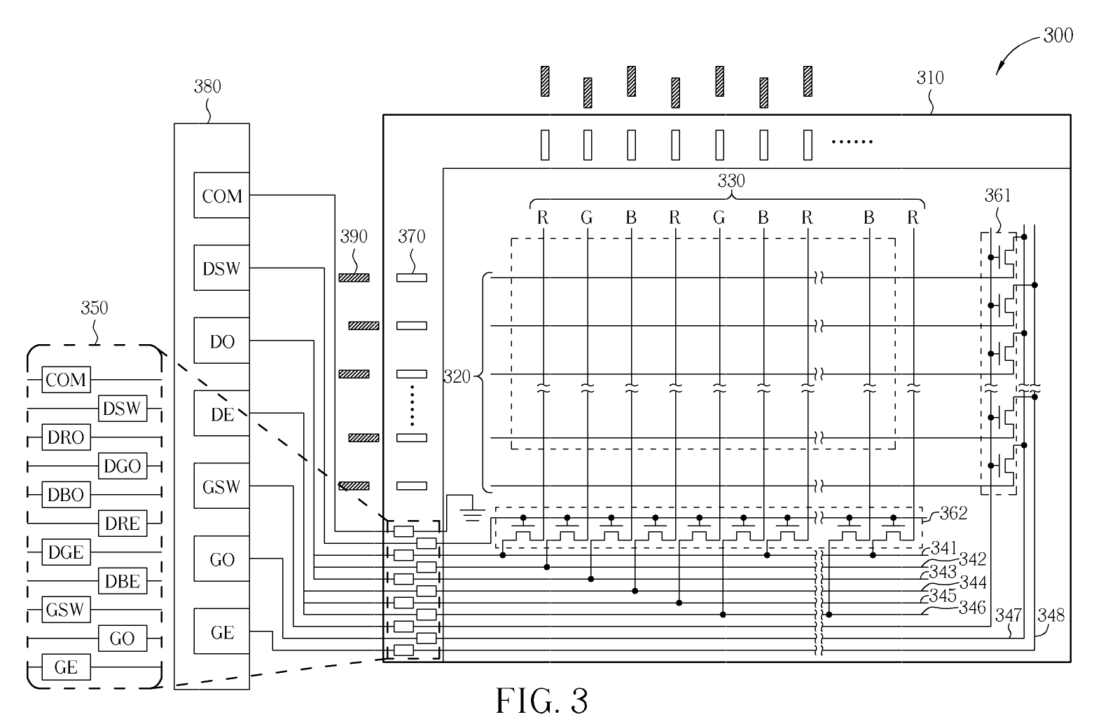

Please refer to FIG. 3. FIG. 3 is a diagram illustrating an LCD panel 300 having shared shorting bars for the array inspection and the panel inspection according to the present invention. The LCD panel 300 comprises a plurality of scan lines 320, a plurality of data lines 330, a plurality of shorting bars 341˜348, a plurality of panel test pads 350, a first set of switches 361, a second set of switches 362, a plurality of driver bonding pads 370, a plurality of array test pads 380, and a plurality of full contact test pads 390. The plurality of scan lines 320, the plurality of data lines 330, the plurality of shorting bars 341˜348, the first set of the switches 361, the second set of the switches 362, and the plurality of driver bonding pads 370 are disposed inside the panel area 310. The plurality of array test pads 380 and the plurality of full contact test pads 390 are disposed outside the panel area 310. During the array inspection of the LCD panel 300, the plurality array test pads 380 inputs the testing signals to the plurality of scan lines 320 and the plurality of data lines 330, through the plurality of shorting bars 341˜348. The part outside the panel area 310 is cut after the panel process. During the panel test of the LCD panel 300, the plurality of panel test pads 350 inputs the testing signals to the plurality of scan lines 320 and the plurality of data lines 330, through the plurality of shorting bars 341˜348. Hence, the plurality of shorting bars 341˜348 can be shared by the array inspection and the panel inspection. In other words, the plurality of shorting bars 341˜348 can be utilized for the array inspection, and can be utilized for the panel test as well, so that the required layout space of the LCD panel 300 can be reduced.

The first set of the switches 361 is electrically connected between the plurality of scan lines 320 and the plurality of shorting bars 347˜348. The second set of the switches 362 is electrically connected between the plurality of data lines 330 and the plurality of shorting bars 341˜346. During the panel test of the LCD panel 300, the first set of the switches 361 and the second set of the switches 362 are turned on. The first shorting bar 341 is electrically connected to the odd red pixel data lines. The second shorting bar 342 is electrically connected to the odd green pixel data lines. The third shorting bar 343 is electrically connected to the odd blue pixel data lines. The fourth shorting bar 344 is electrically connected to the even red pixel data line. The fifth shorting bar 345 is electrically connected to the even green pixel data lines. The sixth shorting bar 346 is electrically connected to the even blue pixel data lines. The seventh shorting bar 347 is electrically connected to the odd scan lines. The eighth shorting bar 348 is electrically connected to the even scan lines.

The plurality of panel test pads 350 comprises a first data test pad DRO, a second data test pad DGO, a third data test pad DBO, a fourth data test pad DRE, a fifth data test pad DGE, a sixth data test pad DBE, a first scan test pad GO, a second scan test pad GE, a common voltage test pad COM, a first switch test pad GSW, and a second switch test pad DSW. The first data test pad DRO is electrically connected to the first shorting bar 341. The second data test pad DGO is electrically connected to the second shorting bar 342. The third data test pad DBO is electrically connected to the third shorting bar 343. The fourth data test pad DRE is electrically connected to the fourth shorting bar 344. The fifth data test pad DGE is electrically connected to the fifth shorting bar 345. The sixth data test pad DBE is electrically connected to the sixth shorting bar 346. The first scan test pad GO is electrically connected to the seventh shorting bar 347. The second scan test bar GE is electrically connected to the eighth shorting bar 348. The common voltage test pad COM is electrically connected to the common voltage source of the LCD panel 300. Generally speaking, the common voltage source is the ground end of the LCD panel 300. The first switch test pad GSW is electrically connected to the control ends of the first set of the switches 361. The second switch test pad DSW is electrically connected to the control ends of the second set of the switches 362.

The plurality of array test pads 380 comprises an odd data test pad DO, an even data test pad DE, an odd scan test pad GO, an even scan test pad GE, a common voltage test pad COM, a first switch test pad GSW and a second switch test pad DSW. The odd data test pad DO is electrically connected to the first data test pad DRO, the second data test pad DGO, and the third data test pad DBO of the panel test pads 350. The even data test pad DE is electrically connected to the fourth data test pad DRE, the fifth data test pad DGE, and the sixth data test pad DBE of the panel test pads 350. The odd scan test pad GO is electrically connected to the first scan test pad GO of the panel test pad 350. The even scan test pad GE is electrically connected to the second scan test pad GE of the panel test pad 350. Besides, the common voltage test pad COM of the array test pad 380, the first switch test pad GSW, and the second switch test pad DSW are respectively electrically connected to the common voltage pads COM, the first switch test pad GSW, and the second switch test pad DSW of the panel test pads 350.

In conclusion, the shorting bars of the LCD panel of the present invention can be shared by the array inspection and the panel inspection. In other words, the shorting bars of the LCD panel of the present invention can be utilized for the array inspection, and can be utilized for the panel test as well. The LCD panel of the present invention comprises a panel area, a plurality of shorting bars, a plurality of panel test pads, and a plurality of array test pads. The panel area comprises a plurality of scan lines and a plurality of data lines. The plurality of shorting bars is disposed inside the panel area. The plurality of scan lines and the plurality of data lines are electrically connected to the corresponding short bars of the plurality of shorting bars through a switch circuit. The plurality of panel test pads is disposed inside the panel area. The plurality of panel test pads is electrically connected to the plurality of shorting bars respectively. The plurality of array test pads is disposed outside the panel area. The plurality of array test pads is electrically connected to the corresponding panel test pads of the plurality of panel test pads. During the panel test, the data lines are not only divided into odd data lines and even data lines, but also divided into red pixel data lines, green pixel data lines, and blue pixel data lines. Consequently, when the plurality of panel test pads is electrically connected to the plurality of array test pads, the odd red pixel data lines, the odd green pixel data lines, and the odd blue pixel data lines are electrically connect together. Meanwhile, the odd red pixel data lines, the odd green pixel data lines, and the odd blue pixel data lines are electrically connect together as well. Since the plurality of shorting bars is shared by the array inspection and the panel inspection, additional shorting bar is not required outside the panel area of the LCD panel, saving the consumed layout space.

Those skilled in the art will readily observe that numerous modifications and alterations of the device and method may be made while retaining the teachings of the invention.

What is claimed is:

1. An LCD panel having shared shorting bars for an array inspection and a panel inspection, comprising:
a panel area, comprising a plurality of scan lines and a plurality of data lines;
a plurality of shorting bars, disposed inside the panel area, the plurality of scan lines and the plurality of data lines electrically connected to corresponding shorting bars of the plurality of shorting bars through a switch circuit;
a plurality of panel test pads, disposed inside the panel area, the plurality of panel test pads electrically connected to the plurality of shorting bars respectively; and
a plurality of array test pads, disposed outside the panel area, the plurality of array test pads electrically connected to corresponding panel test pads of the plurality of panel test pads.

2. The LCD panel of claim 1, wherein the plurality of data lines further comprises a plurality of red pixel data lines, a plurality of green pixel data lines, and a plurality of blue pixel data lines.

3. The LCD panel of claim 2, wherein the plurality of shorting bars comprises:
a first shorting bar, electrically connected to odd red pixel data lines of the plurality of red pixel data lines;
a second shorting bar, electrically connected to odd green pixel data lines of the plurality of green pixel data lines;
a third shorting bar, electrically connected to odd blue pixel data lines of the plurality of blue pixel data lines;
a fourth shorting bar, electrically connected to even red pixel data lines of the plurality of red pixel data lines;
a fifth shorting bar, electrically connected to even green pixel data lines of the plurality of green pixel data lines;
a sixth shorting bar, electrically connected to even blue pixel data lines of the plurality of blue pixel data lines;
a seventh shorting bar, electrically connected to odd scan lines of the plurality of scan lines; and
an eighth shorting bar, electrically connected to even scan lines of the plurality of scan lines.

4. The LCD panel of claim 3, wherein the plurality of panel test pads comprises:
a first data test pad, electrically connected to the first shorting bar;
a second data test pad, electrically connected to the second shorting bar;
a third data test pad, electrically connected to the third shorting bar;
a fourth data test pad, electrically connected to the fourth shorting bar;
a fifth data test pad, electrically connected to the fifth shorting bar;
a sixth data test pad, electrically connected to the sixth shorting bar;
a first scan test pad, electrically connected to the seventh shorting bar; and
a second scan test pad, electrically connected to the eighth shorting bar.

5. The LCD panel of claim 4, wherein the plurality of array test pads comprises:
an odd data test pad, electrically connected to the first data test pad, the second data test pad, and the third data test pad;
an even data test pad, electrically connected to the fourth data test pad, the fifth data test pad, and the sixth data test pad;
an odd scan test pad, electrically connected to the first scan test pad; and
an even scan test pad, electrically connected to the second scan test pad.

6. The LCD panel of claim 1, wherein the switch circuit comprises:
a first set of switches, electrically connected between the plurality of scan lines and the correspond shorting bars of the plurality of shorting bars; and
a second set of switches, electrically connected between the plurality of data lines and the corresponding shorting bars of the plurality of shorting bars.

7. The LCD panel of claim 6, wherein the plurality of panel test pads further comprises:
a common voltage test pad, electrically connected to a common voltage source of the LCD panel;
a first switch test pad, electrically connected to control ends of the first set of the switches; and
a second switch test pad, electrically connected to control ends of the second set of the switches.

8. The LCD panel of claim 7, wherein the plurality of array test pads further comprises:
a common voltage test pad, electrically connected to the common voltage test pad of the plurality of panel test pads;
a first switch test pad, electrically connected to the first switch test pad of the plurality of panel test pads; and
a second switch test pad, electrically connected to the second switch test pad of the plurality of panel test pads.

9. The LCD panel of claim 7, wherein the panel area further comprises a plurality of pixel electrodes electrically connected to the common voltage source of the LCD panel.

10. The LCD panel of claim 1, wherein the switch circuit is turned on for electrically connecting the plurality of shorting bars and the plurality of array test pads when the array inspection of the LCD panel is executed.

11. The LCD panel of claim 10, wherein the plurality of array test pads is cut after the array inspection of the LCD panel.

12. The LCD panel of claim 11, wherein the switch circuit is turned on for electrically connecting the plurality of shorting bars and the plurality of panel test pads when the panel inspection of the LCD panel is executed.

13. The LCD panel of claim 1, wherein the switch circuit is turned on during the array inspection of the LCD panel and the panel inspection of the LCD panel.

14. The LCD panel of claim 1, wherein the plurality of data lines is divided into a group of odd data lines and a group of even data lines for the array inspection of the LCD panel and the panel inspection of the LCD panel.

15. The LCD panel of claim 14, wherein the plurality of data lines is further divided into a group of red pixel data lines, a group of green data lines and a group of blue pixel data lines for the panel inspection of the LCD panel.
